(19) United States
(12) Patent Application Publication
(10) Pub. No.: US 2025/0133931 A1
(43) Pub. Date: Apr. 24, 2025

(54) DISPLAY SUBSTRATE, METHOD FOR MANUFACTURING DISPLAY SUBSTRATE, AND DISPLAY APPARATUS

(71) Applicant: BOE Technology Group Co., Ltd., Beijing (CN)

(72) Inventors: Yansong LI, Beijing (CN); Haidong WU, Beijing (CN); Jingbo XU, Beijing (CN); Xiaobo DU, Beijing (CN); Pengfei ZUO, Beijing (CN); Na BI, Beijing (CN); Xiangmin WEN, Beijing (CN)

(21) Appl. No.: 18/693,340

(22) PCT Filed: Jan. 3, 2023
(86) PCT No.: PCT/CN2023/070186

§ 371 Date: Mar. 19, 2024

(51) Int. Cl. H10K 59/80; H10K 59/12; H10K 59/38; H10K 71/60; H10K 102/00

(52) U.S. Cl. CPC H10K 59/80522; H10K 59/1201; H10K 59/38; H10K 71/60; H10K 2102/331; H10K 2102/351

(57) ABSTRACT

The present disclosure provides a display substrate, a method for manufacturing the display substrate and a display apparatus, wherein the display substrate includes: a base substrate; an anode layer arranged on the base substrate and comprising a plurality of anodes arranged at intervals; a pixel defining layer disposed on the base substrate, the pixel defining layer defining a plurality of pixel areas and covering an edge area of each of the anodes; a light-emitting functional layer arranged on a side of the anode layer away from the base substrate, the light-emitting functional layer at least covering the pixel areas; and a cathode layer and a metal patterning layer arranged on a side of the light-emitting functional layer away from the base substrate.

### TECHNICAL FIELD

The present disclosure relates to the field of display technology, and in particular, to a display substrate, a method for manufacturing the display substrate, and a display apparatus.

### BACKGROUND

An Organic Light-Emitting Diode (OLED) display substrate has the advantages of active light emission, good temperature characteristics, low power consumption, fast response, flexibility, ultra-lightness and thinness, low cost, and the like, and is widely applied to display apparatuses.

### SUMMARY

Embodiments of the present disclosure provide a display substrate, a method for manufacturing the display substrate and a display apparatus, and the specific solutions are as follows.

An embodiment of the present disclosure provides a display substrate, including:
a base substrate;
an anode layer arranged on the base substrate and including a plurality of anodes arranged at intervals;
a pixel defining layer disposed on the base substrate, the pixel defining layer defining a plurality of pixel areas and covering an edge area of each of the anodes;
a light-emitting functional layer arranged on a side of the anode layer away from the base substrate, the light-emitting functional layer at least covering the pixel areas; and
a cathode layer and a metal patterning layer arranged on a side of the light-emitting functional layer away from the base substrate.

In a possible implementation, in the display substrate provided in the embodiment of the present disclosure, the cathode layer is disposed as a whole layer, the metal patterning layer is disposed on a side of the cathode layer away from the base substrate, and the metal patterning layer is disposed in the pixel areas;
the display substrate further includes non-pixel areas between the pixel areas, and the display substrate further includes an auxiliary electrode layer arranged in the non-pixel areas, the auxiliary electrode layer being arranged on the side of the cathode layer away from the base substrate, and the auxiliary electrode layer being in direct contact with the cathode layer.

In a possible implementation, in the display substrate provided in the embodiment of the present disclosure, the auxiliary electrode layer is overlapped with the metal patterning layer to form an overlapping region therebetween.

In a possible implementation, in the display substrate provided in the embodiment of the present disclosure, the metal patterning layer has a thickness ranging from 60 nm to 100 nm, the auxiliary electrode layer has a thickness ranging from 40 nm to 60 nm, an edge area of the metal patterning layer has a slope angle ranging from 1° to 20°, an edge area of the auxiliary electrode layer has a slope angle ranging from 5° to 20°, and the overlapping region has a width ranging from 1 μm to 5 μm.

In a possible implementation, in the display substrate provided in the embodiment of the present disclosure, the metal patterning layer has a thickness ranging from 60 nm to 100 nm, the auxiliary electrode layer has a thickness ranging from 20 nm to 40 nm, an edge area of the metal patterning layer has a slope angle ranging from 1° to 20°, an edge area of the auxiliary electrode layer has a slope angle ranging from 10° to 50°, and the overlapping region has a width less than 1 μm.

In a possible implementation, in the display substrate provided in the embodiment of the present disclosure, the metal patterning layer has a thickness ranging from 10 nm to 30 nm, the auxiliary electrode layer has a thickness more than 100 nm, an edge area of the metal patterning layer has a slope angle ranging from 1° to 20°, an edge area of the auxiliary electrode layer has a slope angle ranging from 160° to 179°, and the overlapping region has a width ranging from 3 μm to 6 μm.

In a possible implementation, in the display substrate provided in the embodiment of the present disclosure, the metal patterning layer has a thickness ranging from 10 nm to 30 nm, the auxiliary electrode layer has a thickness ranging from 30 nm to 100 nm, an edge area of the metal patterning layer has a slope angle ranging from 0.5° to 15°, an edge area of the auxiliary electrode layer has a slope angle ranging from 165° to 179.5°, and the overlapping region has a width ranging from 1 μm to 3 μm.

In a possible implementation, in the display substrate provided in the embodiment of the present disclosure, the metal patterning layer has a thickness ranging from 10 nm to 30 nm, the auxiliary electrode layer has a thickness ranging from 10 nm to 30 nm, an edge area of the metal patterning layer has a slope angle ranging from 0.1° to 30°, an edge area of the auxiliary electrode layer has a slope angle ranging from 150° to 179.9°, and the overlapping region has a width ranging from 0 μm to 1 μm.

In a possible implementation, in the display substrate provided in the embodiment of the present disclosure, the auxiliary electrode layer is not overlapped with the metal patterning layer.

In a possible implementation, in the display substrate provided in the embodiment of the present disclosure, the metal patterning layer has a thickness ranging from 60 nm to 100 nm, the auxiliary electrode layer has a thickness ranging from 10 nm to 20 nm, an edge area of the metal patterning layer has a slope angle ranging from 1° to 20°, an edge area of the auxiliary electrode layer has a slope angle ranging from 30° to 90°, and a gap between adjacent edges of the auxiliary electrode layer and the metal patterning layer has a width ranging from 1 μm to 5 μm.

In a possible implementation, the display substrate provided in the embodiment of the present disclosure further includes a light extraction layer disposed between the cathode layer and the metal patterning layer, the light extraction layer having a pattern identical to a pattern of the metal patterning layer.

In a possible implementation, in the display substrate provided in the embodiment of the present disclosure, the light extraction layer has a thickness ranging from 60 nm to 100 nm, the metal patterning layer has a thickness ranging from 10 nm to 30 nm, the auxiliary electrode layer has a thickness ranging from 30 nm to 100 nm, an edge area of the auxiliary electrode layer has a slope angle ranging from 90° to 170°, the auxiliary electrode layer is overlapped with the metal patterning layer to form an overlapping region therebetween, and the overlapping region has a width ranging from 0 μm to 1 μm.

In a possible implementation, in the display substrate provided in the embodiment of the present disclosure, a ratio of an area of the auxiliary electrode layer to an area of a display area of the display substrate ranges from 30% to 80%.

In a possible implementation, in the display substrate provided in the embodiment of the present disclosure, the metal patterning layer is provided on the side of the light-emitting functional layer away from the base substrate, and the metal patterning layer is provided in non-pixel areas between adjacent pixel areas; and
the cathode layer includes cathodes disposed in the pixel areas.

In a possible implementation, in the display substrate provided in the embodiment of the present disclosure, each cathode is overlapped with the metal patterning layer to form an overlapping region therebetween.

In a possible implementation, in the display substrate provided in the embodiment of the present disclosure, the metal patterning layer has a thickness ranging from 60 nm to 100 nm, each cathode has a thickness ranging from 10 nm to 20 nm, an edge area of the metal patterning layer has a slope angle ranging from 1° to 20°, an edge area of each cathode has a slope angle ranging from 1° to 30°, and the overlapping region has a width ranging from 1 μm to 5 μm.

In a possible implementation, in the display substrate provided in the embodiment of the present disclosure, each cathode is not overlapped with the metal patterning layer.

In a possible implementation, in the display substrate provided in the embodiment of the present disclosure, the metal patterning layer has a thickness ranging from 60 nm to 100 nm, each cathode has a thickness ranging from 1 nm to 10 nm, an edge area of the metal patterning layer has a slope angle ranging from 1° to 20°, an edge area of each cathode has a slope angle ranging from 3° to 90°, and a gap between adjacent edges of each cathode and the metal patterning layer has a width ranging from 0.1 μm to 2 μm.

In a possible implementation, in the display substrate provided in the embodiment of the present disclosure, the pixel areas include a red pixel area, a green pixel area, and a blue pixel area, the cathode layer is disposed as a whole layer, the metal patterning layer is disposed on a side of the cathode layer away from the base substrate, and the metal patterning layer is disposed in the green pixel area and the blue pixel area, a thickness of a portion of the cathode layer corresponding to the red pixel area is greater than each of thicknesses of portions of the cathode layer corresponding to the green pixel area and the blue pixel area, the thicknesses of the portions of the cathode layers corresponding to the green pixel area and the blue pixel area being the same.

In a possible implementation, in the display substrate provided in the embodiment of the present disclosure, a material of the metal patterning layer is an organic transparent material and the metal patterning layer has a transmittance greater than 90%.

In a possible implementation, in the display substrate provided in the embodiment of the present disclosure, a material of the metal patterning layer includes: N,N′-diphenyl-N,N-bis(9-phenyl-9H-carbazol-3-yl)biphenyl-4,4′-diamine, N-(biphenyl-4-yl)-9,9-dimethyl-N-(4-(9-phenyl-9H-carbazol-3-yl)phenyl)-9H-fluoren-2-amine, 4,4′,4″-tris(3-methylphenylphenylamino)triphenylamine, N,N′-bis(1-naphthyl)-N,N′-diphenyl[1,1′-biphenyl]-4,4′-diamine, 4,4′-bis[N-(3-methylphenyl)-N-phenylamino]biphenyl, N4,N4′-diphenyl-N4,N4′-bis(9-phenyl-9H-carbazol-3-yl)diphenyl-4,4′-diamine, or N(diphenyl-4-yl)9,9-dimethyl-N-(4(9-phenyl-9H-carbazol-3-yl)phenyl)-9H-fluoren-2-amine.

In a possible implementation, in the display substrate provided in the embodiment of the present disclosure, the auxiliary electrode layer includes a single layer of metal; or the auxiliary electrode layer includes at least two layers of metal which are stacked together and different in material.

In a possible implementation, in the display substrate provided in the embodiment of the present disclosure, the material of each layer of the metal includes Mg, Ag, Al, Li, K, Ca, MgₓAg₍₁₋ₓ₎, LiₓAl₍₁₋ₓ₎, LiₓCa₍₁₋ₓ₎, or LiₓAg₍₁₋ₓ₎.

Correspondingly, an embodiment of the present disclosure further provides a display apparatus, which includes the above-mentioned display substrate.

In a possible implementation, the display apparatus provided in the embodiment of the present disclosure further includes: further including: a color filter layer arranged on a side of the base substrate away from the cathode layer, and an encapsulation layer arranged on a side of the cathode layer away from the base substrate, where
the light-emitting functional layer includes a hole injection layer, a first hole transport layer, a first blue light-emitting layer, a first electron transport layer, an N-type charge generation layer, a P-type charge generation layer, a second hole transport layer, a second blue light-emitting layer, a second electron transport layer and an electron injection layer which are sequentially stacked and arranged between the anodes and the cathode layer, and the hole injection layer is close to the anodes.

In a possible implementation, the display apparatus provided in the embodiment of the present disclosure further includes: a light extraction layer, an encapsulation layer, a quantum dot color conversion layer and a color filter layer which are stacked together and arranged on a side of the cathode layer away from the base substrate, where
the light-emitting functional layer includes a hole injection layer, a first hole transport layer, a first blue light-emitting layer, a first electron transport layer, an N-type charge generation layer, a P-type charge generation layer, a second hole transport layer, a second blue light-emitting layer, a second electron transport layer and an electron injection layer which are sequentially stacked and arranged between the anodes and the cathode layer, and the hole injection layer is close to the anodes.

Correspondingly, an embodiment of the present disclosure further provides a method for manufacturing the above-mentioned display substrate provided by the embodiment of the present disclosure, and the method includes:
manufacturing the anode layer including the plurality of anodes arranged at intervals on the base substrate;
manufacturing the pixel defining layer on the side of the cathode layer away from the base substrate, the pixel defining layer defining the plurality of pixel areas and covering the edge area of each anode;
manufacturing the light-emitting functional layer on the side of the anode layer away from the base substrate, the light-emitting functional layer at least covering the pixel areas; and
manufacturing the cathode layer and the metal patterning layer on the side of the light-emitting functional layer away from the base substrate.

In a possible implementation manner, in the above method provided in the embodiment of the present disclosure, the manufacturing the cathode layer and the metal patterning layer on the side of the light-emitting functional layer away from the base substrate includes:
manufacturing the cathode layer arranged as a whole layer on the side of the light-emitting functional layer away from the base substrate;
depositing a metal patterning material film layer on a side of the cathode layer away from the base substrate, and patterning the metal patterning material film layer to form the metal patterning layer which is arranged in the pixel areas and is arranged on the side of the cathode layer away from the base substrate; and
depositing a metal material on a side of the metal patterning layer away from the base substrate to form an auxiliary electrode layer, which is in direct contact with the cathode layer, in non-pixel areas.

In a possible implementation manner, in the above method provided in the embodiment of the present disclosure, the manufacturing the cathode layer and the metal patterning layer on the side of the light-emitting functional layer away from the base substrate includes:
depositing a metal patterning material film layer on the side of the light-emitting functional layer away from the base substrate, and patterning the metal patterning material film layer to form the metal patterning layer arranged in non-pixel areas; and
depositing a metal material on a side of the metal patterning layer away from the base substrate to form the cathode layer in the pixel areas.

In a possible implementation, in the above method provided in the embodiment of the present disclosure, the manufacturing the cathode layer and the metal patterning layer on the side of the light-emitting functional layer away from the base substrate includes:
manufacturing a first cathode layer arranged as a whole layer on the side of the light-emitting functional layer away from the base substrate;
depositing a metal patterning material film layer on a side of the first cathode layer away from the base substrate, and patterning the metal patterning material film layer to form the metal patterning layer in a green pixel area and a blue pixel area; and
depositing a metal material on a side of the metal patterning layer away from the base substrate, to form a second cathode layer which is in direct contact with the first cathode layer in a red pixel area, the first cathode layer and the second cathode layer constituting the cathode layer.

### BRIEF DESCRIPTION OF DRAWINGS

FIG. 1A is a schematic structural diagram of a display substrate according to an embodiment of the present disclosure;

FIG. 1B is an enlarged schematic diagram of a portion of a structure in FIG. 1A;

FIG. 2A is a schematic structural diagram of a display substrate according to an embodiment of the present disclosure;

FIG. 2B is an enlarged schematic view of a portion of a structure in FIG. 2A;

FIG. 3A is a schematic structural diagram of a display substrate according to an embodiment of the present disclosure;

FIG. 3B is an enlarged schematic diagram of a portion of a structure in FIG. 3A;

FIG. 4A is a schematic structural diagram of a display substrate according to an embodiment of the present disclosure;

FIG. 4B is an enlarged schematic diagram of a portion of a structure in FIG. 4A;

FIG. 5A is a schematic structural diagram of a display substrate according to an embodiment of the present disclosure;

FIG. 5B is an enlarged schematic view of a portion of a structure in FIG. 5A;

FIG. 6A is a schematic structural diagram of a display substrate according to an embodiment of the present disclosure;

FIG. 6B is an enlarged schematic diagram of a portion of a structure in FIG. 6A;

FIG. 7A is a schematic structural diagram of a display substrate according to an embodiment of the present disclosure;

FIG. 7B is an enlarged schematic diagram of a portion of a structure in FIG. 7A;

FIG. 8A is a schematic structural diagram of a display substrate according to an embodiment of the present disclosure;

FIG. 8B is an enlarged schematic diagram of a portion of a structure in FIG. 8A;

FIG. 9A is a schematic structural diagram of a display substrate according to an embodiment of the present disclosure;

FIG. 9B is an enlarged schematic diagram of a portion of a structure in FIG. 9A;

FIG. 10 shows decay curves of brightness of primary red and green light in an actual display product;

FIG. 11 is a schematic structural diagram of a display substrate according to an embodiment of the present disclosure;

FIG. 12 shows decay curves of brightness of red and green light in a display substrate according to an embodiment of the present disclosure;

FIG. 13 is a schematic flow chart illustrating a method for manufacturing a display substrate according to an embodiment of the present disclosure;

FIG. 14 is a schematic flow chart illustrating a method for manufacturing a display substrate according to an embodiment of the present disclosure;

FIG. 15A and FIG. 15B are schematic cross-sectional views each illustrating a structure obtained after performing each step of a method for manufacturing a display substrate according to an embodiment of the present disclosure;

FIG. 16 is a schematic flow chart illustrating a method for manufacturing a display substrate according to an embodiment of the present disclosure;

FIG. 17 is a schematic cross-sectional view illustrating a structure obtained by performing a manufacturing step of a method for manufacturing a display substrate according to an embodiment of the present disclosure;

FIG. 18 is a schematic flow chart illustrating a method for manufacturing a display substrate according to an embodiment of the present disclosure;

FIGS. 19A to 19C are schematic cross-sectional views each illustrating a structure obtained by performing each step of a method for manufacturing a display substrate according to an embodiment of the present disclosure;

FIG. 20 is a schematic structural diagram of a display apparatus according to an embodiment of the present disclosure;

FIG. 21 is a schematic structural diagram of a display apparatus according to an embodiment of the present disclosure; and

FIG. 22 is a schematic plan view of a display apparatus according to an embodiment of the present disclosure.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few embodiments of the present disclosure, not all embodiments. Furthermore, the embodiments and features of the embodiments in the present disclosure may be combined with each other without conflict. All other embodiments, which can be derived by those skilled in the art from the described embodiments of the disclosure without inventive step, are within the scope of protection of the disclosure.

Unless defined otherwise, technical or scientific terms used herein shall have the ordinary meaning as understood by those skilled in the art to which this disclosure belongs. The use of “including/comprising” or “comprises/includes” and the like in the present disclosure is intended to mean that the element or item preceding the word comprises/includes the element or item listed after the word and its equivalent, but does not exclude other elements or items. The terms “connected/coupled” or “coupling/connecting” and the like are not restricted to physical or mechanical connections, but may include electrical connections, whether direct indirect. The terms “inner/in/inside”, “outer/out/outside”, “upper/on/above”, “lower/below/under”, and the like are used merely to indicate relative positional relationships, and when the absolute position of the object being described is changed, the relative positional relationships may also be changed accordingly.

It should be noted that sizes and shapes of various figures in the drawings are not to scale, but are merely intended to illustrate the present disclosure. Like reference numerals refer to like or similar elements or elements having like or similar functions throughout.

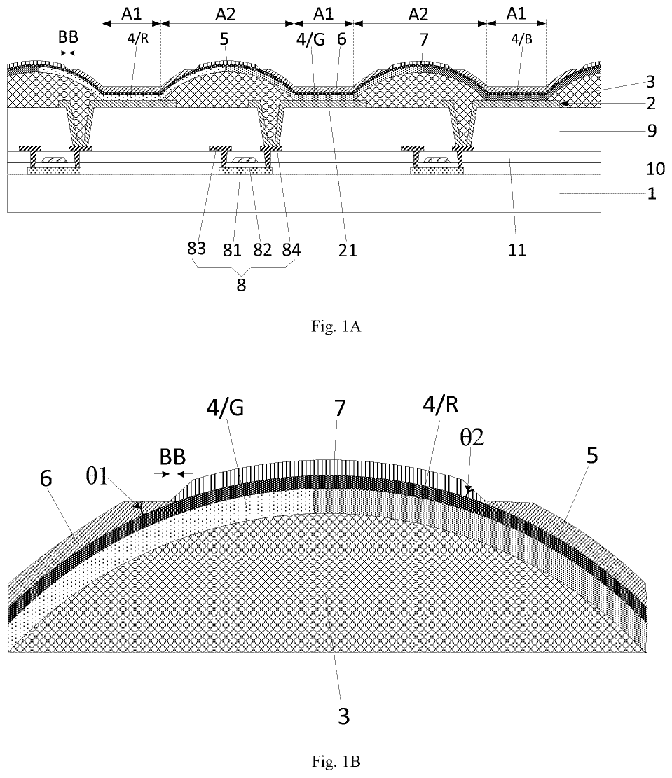

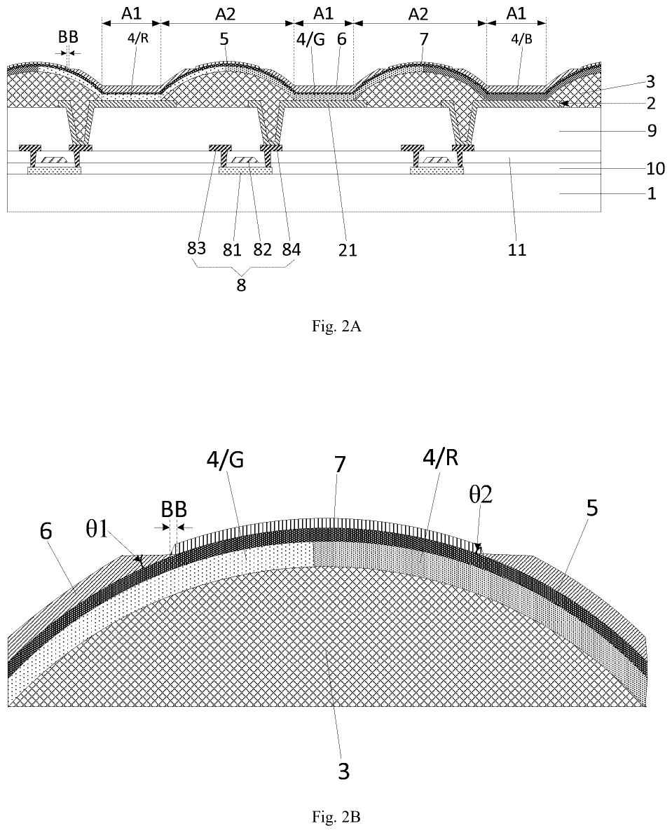

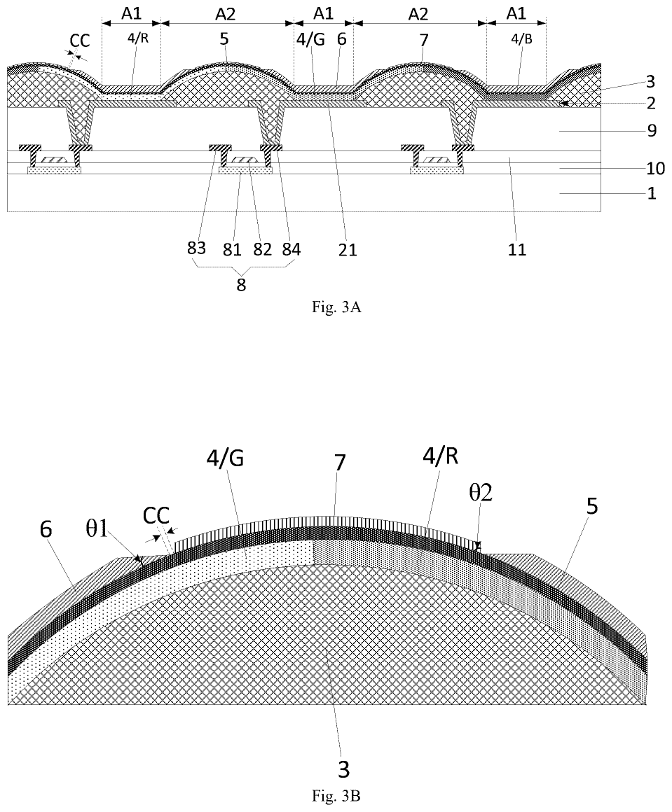

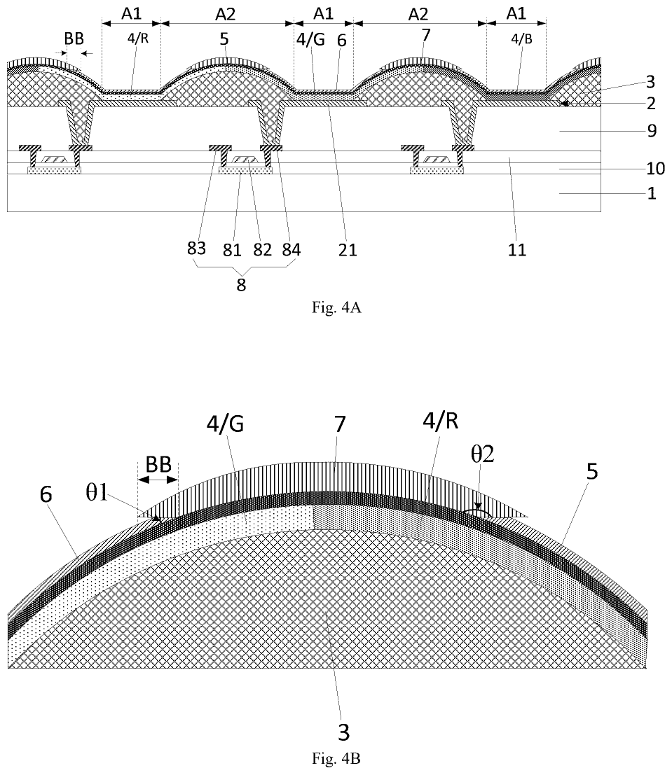

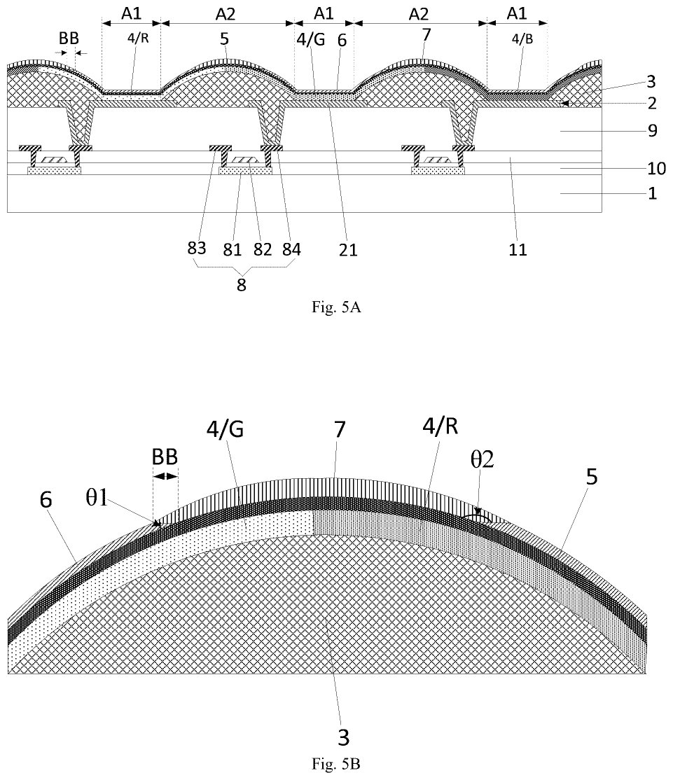

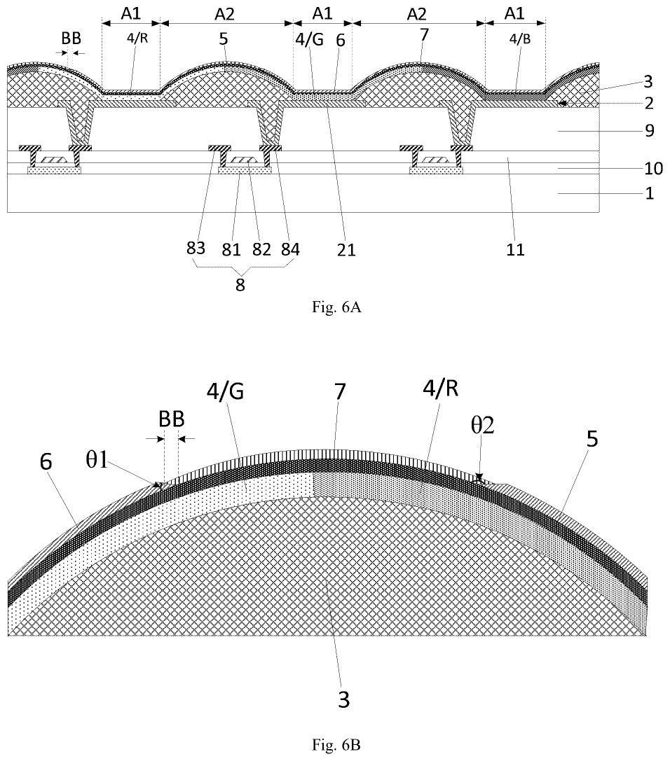

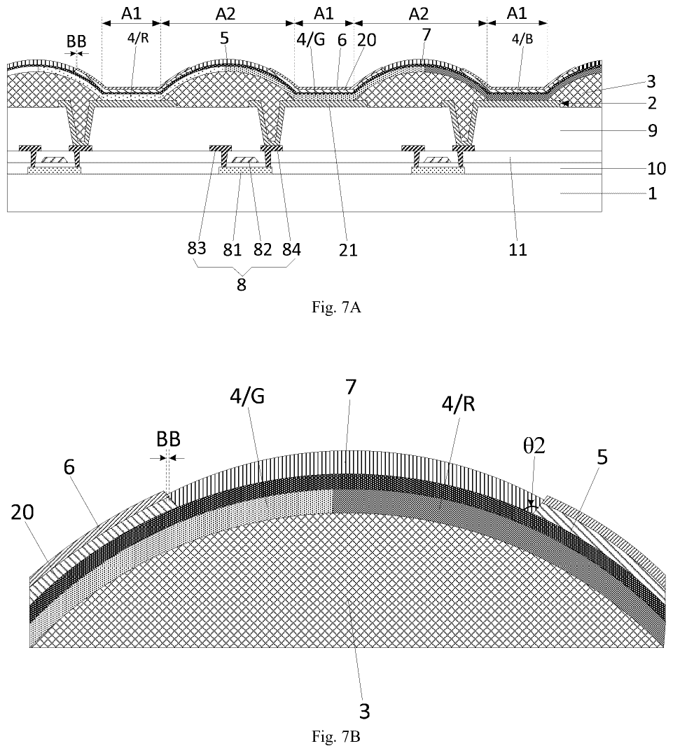

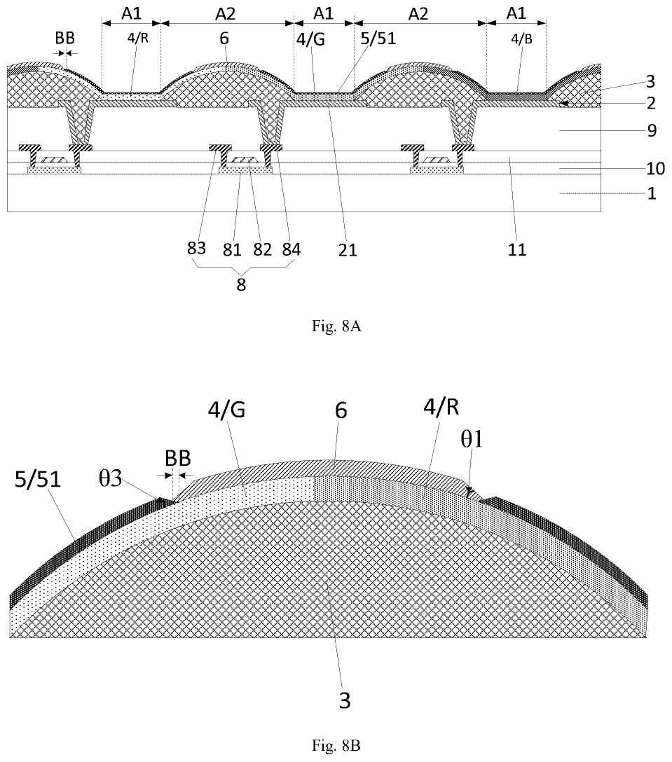

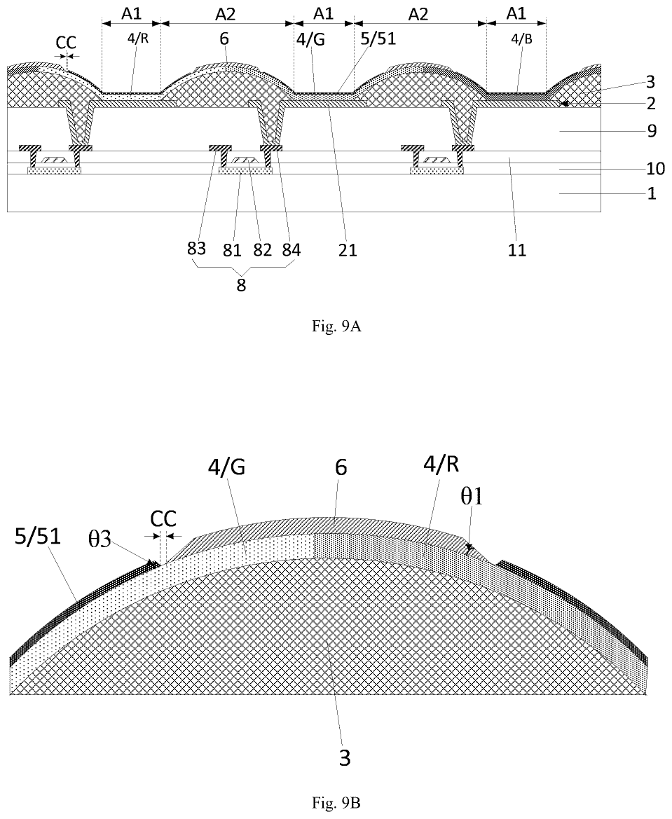

Embodiments of the present disclosure provide display substrates, as shown in FIG. 1A, FIG. 2A, FIG. 3A, FIG. 4A, FIG. 5A, FIG. 6A, FIG. 7A, FIG. 8A, and FIG. 9A, each display substrate may include:
a base substrate 1;
an anode layer 2 disposed on the base substrate 1, the anode layer 2 including a plurality of anodes 21 disposed at intervals;
a pixel defining layer 3 disposed on the base substrate 1, the pixel defining layer 3 defining a plurality of pixel areas A1 and covering an edge area of each anode 21;
a light-emitting functional layer 4 arranged on a side, away from the base substrate 1, of the anode layer 2, the light-emitting functional layer 4 at least covering the pixel areas A1; and
a cathode layer 5 and a metal patterning layer 6 arranged on a side of the light-emitting functional layer 4 away from the base substrate 1.

It should be noted that the metal patterning layer 6 is made of cathode patterning material (CPM), and the CPM is a material for only selectively depositing a cathode material, so that the cathode material is difficult to attach on the CPM, and a purpose of avoiding the attachment of the cathode material in a corresponding area can be achieved as desired.

In the above-mentioned display substrates provided in the embodiments of the present disclosure, the cathode layer and the metal patterning layer are provided on a side of the light-emitting functional layer away from the base substrate, so that an overall transmissivity of the display substrate can be improved by reasonably arranging the position of metal patterning layer, in addition, an auxiliary electrode layer (which is made of the same material as that of the cathode) that is electrically connected to the cathode layer may be further provided, the resistance of the cathode layer can be reduced, the IR drop of the cathode layer can be reduced, and the uniform distribution of voltage drop among the pixel areas can be achieved, thereby improving the uniformity of light emission and display quality of the display substrate.

At present, compared with bottom-emitting light-emitting devices, top-emission type light-emitting devices are widely applied due to relatively high aperture ratio thereof, and since the top-emission type light-emitting devices have higher requirement on the transmittance of the cathode layer, a thickness of the cathode layer is desired to be less than 20 nm. The thinner the cathode layer is, the higher the resistance of the cathode layer is, which causes a significant difference in brightness at different positions of the display product, and affects the visual experience for the display product. Therefore, in order to reduce the resistance of the cathode layer, in the display substrate provided in the embodiment of the present disclosure, as shown in FIG. 1A, FIG. 2A, FIG. 3A, FIG. 4A, FIG. 5A, FIG. 6A, and FIG. 7A, the cathode layer 5 may be provided as an entire layer, the metal patterning layer 6 is provided on the side of the cathode layer 5 away from the base substrate 1, and the metal patterning layer 6 is provided in the pixel areas A1.

An area between any two adjacent pixel areas A1 is a non-pixel area A2, the display substrate further includes an auxiliary electrode layer 7 disposed in the non-pixel areas A2, the auxiliary electrode layer 7 is disposed on a side of the cathode layer 5 away from the base substrate 1, and the auxiliary electrode layer 7 is in direct contact with the cathode layer 5. In this way, in the embodiment of the present disclosure, before forming the auxiliary electrode layer 7, the patterned metal patterning layer 6 to be disposed on the side of the cathode layer 5 away from the base substrate 1 is formed in the pixel areas A1, so that when forming the auxiliary electrode layer 7, due to the selection performance of the metal patterning layer 6 for the metal material, the metal material used for the auxiliary electrode layer 7 is difficult to be deposited on the metal patterning layer 6, that is, the auxiliary electrode layer 7 is not formed in the pixel areas A1, and the auxiliary electrode layer 7 in parallel contact with the cathode layer 5 is formed in the non-pixel areas A2, thereby reducing the resistance of the cathode layer 5 without reducing the transmittance of the pixel areas A1.

In a practical implementation, parameters, such as an area and a thickness, of the metal patterning layer may be set by combining requirements on the light transmittance of the display substrate, a size of the display substrate and a resistance reduction of the auxiliary electrode layer, and then an expected size of the auxiliary electrode layer can be obtained. In the above-mentioned display substrate provided in the embodiment of the present disclosure, a ratio of an area of the auxiliary electrode layer to a display area of the display substrate ranges from 30% to 80%. For example, the ratio of the area of the auxiliary electrode layer to the display area of the display substrate may be 30%, 40%, 50%, 60%, 70%, 80%, or the like.

In a practical implementation, in the display substrate provided in the embodiment of the present disclosure, a material of the metal patterning layer may be an organic transparent material, and a transmittance of the metal patterning layer is greater than 90%, so that the metal patterning layer does not affect an overall transmittance of the display substrate.

Alternatively, the material patterning layer may include: N,N′-diphenyl-N,N-bis(9-phenyl-9H-carbazol-3-yl)biphenyl-4,4′-diamine, N-(biphenyl-4-yl)-9,9-dimethyl-N-(4-(9-phenyl-9H-carbazol-3-yl)phenyl)-9H-fluoren-2-amine, 4,4′,4″-tris(3-methylphenylphenylamino)triphenylamine, N,N′-bis(1-naphthyl)-N,N′-diphenyl[1,1′-biphenyl]-4,4′-diamine, 4,4′-bis[N-(3-methylphenyl)-N-phenylamino]biphenyl, N4,N4′-diphenyl-N4,N4′-bis(9-phenyl-9H-carbazol-3-yl)diphenyl-4,4′-diamine, or N(diphenyl-4-yl)9,9-dimethyl-N-(4(9-phenyl-9H-carbazol-3-yl)phenyl)-9H-fluoren-2-amine.

In a practical implementation, the auxiliary electrode layer may include a single layer of metal; or the auxiliary electrode layer may include at least two layers of metal stacked together, the layers of metal being different in material. Alternatively, the material of each layer of metal may include Mg, Ag, Al, Li, K, Ca, MgₓAg₍₁₋ₓ₎, LiₓAl₍₁₋ₓ₎, LiₓCa₍₁₋ₓ₎, or LiₓAg₍₁₋ₓ₎. The adhesion between the material of the above-mentioned metal patterning layer and the above-mentioned metal materials or alloy materials is relatively low. Therefore, it is difficult to deposit the above-mentioned metal materials or alloy materials on the metal patterning layer.

In a practical implementation, the auxiliary electrode layer and the metal patterning layer may have different deposition thicknesses, and may or may not have overlapping regions at adjacent edges thereof. In the display substrate provided in the embodiment of the present disclosure, as shown in FIG. 1A, FIG. 1B, FIG. 2A, FIG. 2B, FIG. 4A, FIG. 4B, FIG. 5A, FIG. 5B, FIG. 6A, and FIG. 6B, where FIG. 1B is an enlarged schematic diagram of a portion of a structure in FIG. 1A, FIG. 2B is an enlarged schematic diagram of a portion of a structure in FIG. 2A, FIG. 4B is an enlarged schematic diagram of a portion of a structure in FIG. 4A, FIG. 5B is an enlarged schematic diagram of a portion of a structure in FIG. 5A, and FIG. 6B is an enlarged schematic diagram of a portion of a structure in FIG. 6A, the auxiliary electrode layer 7 and the metal patterning layer 6 have an overlapping regions BB.

In some implementations, as shown in FIGS. 1A and 1B, a thickness of the metal patterning layer 6 may range from 60 nm to 100 nm, a thickness of the auxiliary electrode layer 7 may range from 40 nm to 60 nm, a slope angle θ1 of an edge area of the metal patterning layer 6 ranges from 1° to 20°, a slope angle θ2 of an edge area of the auxiliary electrode layer 7 ranges from 5° to 20°, and a width of the overlapping region BB ranges from 1 μm to 5 μm. A mutual exclusion effect on the material of the auxiliary electrode layer 7 can only be achieved in a case where the thickness of the metal patterning layer 6 exceeds 20 nm, and there is residual metal material of the auxiliary electrode layer 7 in a region of the metal patterning layer 6 with a thickness less than 20 nm, therefore, the auxiliary electrode layer 7 and the metal patterning layer 6 are overlapped at the edge areas thereof.

In some implementations, as shown in FIGS. 2A and 2B, a thickness of the metal patterning layer 6 may range from 60 nm to 100 nm, and a thickness of the auxiliary electrode layer 7 may range from 20 nm to 40 nm, preferably from 20 nm to 30 nm; a slope angle θ1 of the edge area of the metal patterning layer 6 ranges from 1° to 20°, a slope angle θ2 of an edge area of the auxiliary electrode layer 7 ranges from 10° to 20°, and a width of the overlapping region BB is smaller than 1 μm. A mutual exclusion effect on the material of the auxiliary electrode layer 7 can only be achieved in a case where the thickness of the metal patterning layer 6 exceeds 20 nm, and there is residual metal material of the auxiliary electrode layer 7 in a region of the metal patterning layer 6 with a thickness less than 20 nm, therefore, the auxiliary electrode layer 7 and the metal patterning layer 6 are overlapped at the edge areas thereof, and the greater the thickness of the metal patterning layer 6 is than the thickness of the auxiliary electrode layer 7, the smaller the width of the overlapping area BB is, and the more beneficial it is to reducing the process difficulty.

In some implementations, as shown in FIGS. 4A and 4B, a thickness of the metal patterning layer 6 may range from 10 nm to 30 nm, a thickness of the auxiliary electrode layer 7 may be greater than 100 nm, a slope angle θ1 of an edge area of the metal patterning layer 6 ranges from 1° to 20°, a slope angle θ2 of an edge area of the auxiliary electrode layer 7 ranges from 160° to 179°, and a width of the overlapping region BB ranges from 3 μm to 6 μm.

In some implementations, as shown in FIGS. 5A and 5B, a thickness of the metal patterning layer 6 may range from 10 nm to 30 nm, and a thickness of the auxiliary electrode layer 7 may range from 30 nm to 100 nm, preferably from 50 nm to 100 nm; a slope angle θ1 of an edge area of the metal patterning layer 6 ranges from 0.5° to 15°, a slope angle θ2 of an edge area of the auxiliary electrode layer 7 ranges from 165° to 179.5°, and a width of the overlapping region BB ranges from 1 μm to 3 μm.

In some implementations, as shown in FIGS. 6A and 6B, a thickness of the metal patterning layer 6 may range from 10 nm to 30 nm, a thickness of the auxiliary electrode layer 7 may range from 10 nm to 30 nm, and a slope angle θ1 of an edge area of the metal patterning layer 6 ranges from 0.1° to 30°, preferably from 1° to 20°, a slope angle θ2 of an edge area of the auxiliary electrode layer 7 ranges from 150° to 179.9°, and a width of the overlapping region BB ranges from 0 μm to 1 μm.

As can be seen from FIGS. 4A, 5A and 6A, the greater the thickness of the metal patterning layer 6 is than the thickness of the auxiliary electrode layer 7, the smaller the width of the overlapping area BB is, and the more beneficial it is to reducing the process difficulty.

In a practical implementation, the auxiliary electrode layer and the metal patterning layer are deposited in different thicknesses, and may or may not have overlapping regions at adjacent edges thereof. In the display substrate provided in the embodiment of the present disclosure, as shown in FIGS. 3A and 3B, where FIG. 3B is an enlarged schematic diagram of a portion of the structure in FIG. 3A, the auxiliary electrode layer 7 is not overlapped with the metal patterning layer 6.

In some implementations, as shown in FIGS. 3A and 3B, a thickness of the metal patterning layer 6 may range from 60 nm to 100 nm, a thickness of the auxiliary electrode layer 7 may range from 10 nm to 20 nm, a slope angle θ1 of an edge area of the metal patterning layer 6 ranges from 1° to 20°, a slope angle θ2 of an edge area of the auxiliary electrode layer 7 ranges from 30° to 90°, and a width of a gap CC between adjacent edges of the auxiliary electrode layer 7 and the metal patterning layer 6 ranges from 1 μm to 5 μm. In the present embodiment, since the thickness of the metal patterning layer 6 exceeds 50 nm, it may further have a mutually exclusive effect on the material of the auxiliary electrode layer 7 in a horizontal direction, so that the gap appears between the adjacent edges of the auxiliary electrode layer 7 and the metal patterning layer 6. Therefore, by designing the thickness of the metal patterning layer 6 to be much greater than that of the auxiliary electrode layer 7, the metal patterning layer 6 and the auxiliary electrode layer 7 can be prevented from being overlapped, and the process difficulty can be reduced.

Specifically, as shown in FIG. 1A, FIG. 1B, FIG. 2A, FIG. 2B, FIG. 3A, FIG. 3B, FIG. 4A, FIG. 4B, FIG. 5A, FIG. 5B, FIG. 6A, and FIG. 6B, since the metal patterning layer 6 has a relatively great thickness, the metal patterning layer 6 can simultaneously perform the dual functions of selectively depositing the auxiliary electrode layer 7 and multiplexing as a light extraction layer, so as to achieve the improvement of the light extraction efficiency of the cathode layer 5 in addition to reducing the resistance of the cathode layer 5.

In a specific implementation, in order to improve the light extraction efficiency of the cathode layer, as shown in FIGS. 7A and 7B, the display substrate provided in the embodiment of the present disclosure further includes a light extraction layer 20 disposed between the cathode layer 5 and the metal patterning layer 6, and a pattern of the light extraction layer 20 is the same as that of the metal patterning layer 6. With the light extraction layer 20, the light extraction efficiency of the cathode layer 5 can be improved by 10% to 20%.

In a specific implementation, as shown in FIGS. 7A and 7B, in the display substrate provided in the embodiment of the present disclosure, a thickness of the light extraction layer 20 may range from 60 nm to 100 nm, a thickness of the metal patterning layer 6 may range from 10 nm to 30 nm, a thickness of the auxiliary electrode layer 7 may range from 30 nm to 100 nm, a slope angle θ2 of an edge area of the auxiliary electrode layer 7 ranges from 90° to 170°, the auxiliary electrode layer 7 and the metal patterning layer 6 have an overlapping region BB therebetween, and a width of the overlapping region BB ranges from 0 μm to 1 μm.

With the development of display technology, present display products have increasingly high requirements for the transmittance of the cathode layer, on the one hand, increasing the transmittance of the cathode layer can improve color cast with viewing angle, and on the other hand, increasing the transmittance of the cathode layer is more beneficial to the application of under-screen camera technology, which can enhance the photography effect of the under-screen camera. Therefore, in the above-mentioned display substrate provided in the embodiment of the present disclosure, as shown in FIG. 8A, FIG. 8B, FIG. 9A and FIG. 9B, where FIG. 8B is an enlarged schematic diagram of a portion of the structure in FIG. 8A, and FIG. 9B is an enlarged schematic diagram of a portion of the structure in FIG. 9A, the metal patterning layer 6 may be disposed on a side of the light-emitting functional layer 4 away from the base substrate 1, and the metal patterning layer 6 is disposed in the non-pixel areas A2 between the adjacent pixel areas A1.

The cathode layer 5 includes cathodes 51 provided in the pixel areas A1. In the embodiment of the present disclosure, before forming the cathode layer 5, the patterned metal patterning layer 6 disposed on the side of the light-emitting functional layer 4 away from the base substrate 1 is formed in the non-pixel areas A2, so that when forming the cathode layer 5, due to the selection performance of the metal patterning layer 6 for the material of the cathode, the material of the cathode is difficult to deposit on the metal patterning layer 6, that is, no cathode is formed in the non-pixel areas A2, the cathodes 51 are formed in the pixel areas A1, and since the cathodes 51 are formed only in the pixel areas A1, the overall transmittance of the display substrate can be improved, which is beneficial for improving the application of the under-screen camera technology, for example, improving the photography effect of the under-screen camera.

In a practical implementation, the cathode and the metal patterning layer are deposited in different thicknesses, and may or may not have an overlapping region at adjacent edges thereof, and in the display substrate provided in the embodiment of the present disclosure, as shown in FIGS. 8A and 8B, each cathode 51 and the metal patterning layer 6 have an overlapping region BB therebetween.

In some implementations, as shown in FIGS. 8A and 8B, a thickness of the metal patterning layer 6 may range from 60 nm to 100 nm, a thickness of the cathode 51 may range from 10 nm to 20 nm, a slope angle θ1 of an edge area of the metal patterning layer 6 ranges from 1° to 20°, a slope angle θ3 of an edge area of the cathode 51 ranges from 1° to 30°, and a width of the overlapping region BB ranges from 1 μm to 5 μm.

In a practical implementation, each cathode and the metal patterning layer are deposited in different thicknesses, and may or may not have an overlapping region at adjacent edges thereof, and in the display substrate provided in the embodiment of the present disclosure, as shown in FIGS. 9A and 9B, each cathode and the metal patterning layer do not overlap.

In soma implementations, as shown in FIGS. 9A and 9B, a thickness of the metal patterning layer 6 may range from 60 nm to 100 nm, a thickness of each cathode 51 may range from 1 nm to 10 nm, a slope angle θ1 of an edge area of the metal patterning layer 6 ranges from 1° to 20°, a slope angle θ3 of an edge area of the cathode 51 ranges from 3° to 90°, and a width of a gap CC between adjacent edges of the cathode 51 and the metal patterning layer 6 ranges from 0.1 μm to 2 μm. In the present embodiment, since the thickness of the metal patterning layer 6 exceeds 50 nm, it may further have a mutually exclusive effect on the material of the auxiliary electrode layer 7 in a horizontal direction, so that the gap appears between the adjacent edges of the cathode 51 and the metal patterning layer 6. By designing the thickness of the metal patterning layer 6 to be much greater than that of the cathode 51, the metal patterning layer 6 and the cathode 51 are not overlapped, and the process difficulty can be reduced.

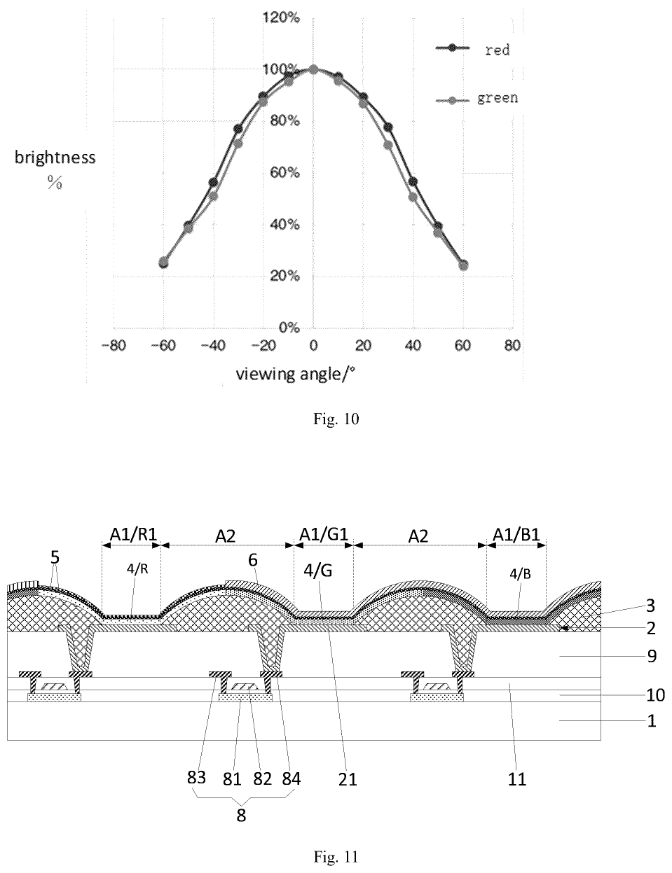

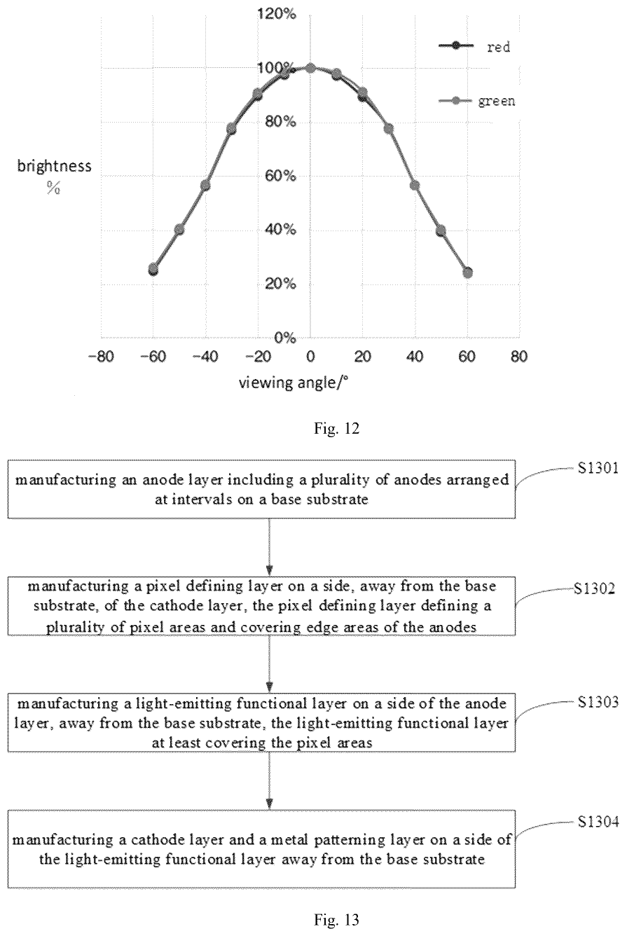

In a specific implementation, the pixel areas of the display substrate provided by the embodiment of the disclosure may include a red pixel area, a green pixel area, and a blue pixel area. For example, FIG. 10 shows decay curves of brightness of primary red and green light in an actual display product, and since a decay speed of brightness of the blue light with an viewing angle is equivalent to that of the green light, only the red light and the green light are compared in FIG. 10, and it can be found from FIG. 10 that the decay speed of the brightness of the red light with the viewing angle is slower than the decay speed of the brightness of the green light with the viewing angle, thereby causing ununiform display brightness in the actual display. In order to solve this problem, in the above display substrate provided in the embodiment of the present disclosure, as shown in FIG. 11, the pixel areas A1 include a red pixel area R1, a green pixel area G1, and a blue pixel area B1, the cathode layer 5 is disposed as a whole layer, the metal patterning layer 6 is disposed on a side of the cathode layer 5 away from the base substrate 1, and the metal patterning layer 6 is disposed in the green pixel area G1 and the blue pixel area B1, a thickness of a portion of the cathode layer 5 corresponding to the red pixel area R1 is greater than each of thicknesses of portions of the cathode layer 5 corresponding to the green pixel area G1 and the blue pixel area B1, and the thicknesses of the portions of the cathode layer 5 corresponding to the green pixel area G1 and the blue pixel area B1 are the same. Therefore, in the present embodiment, the cathode layer 5 with uniform thickness and disposed as the whole layer may be firstly formed on the side of the light-emitting functional layer 4 away from the base substrate 1, then the patterned metal patterning layer 6 is formed in the green pixel area G1 and the blue pixel area B1, next the material for the cathode layer is redeposited in the red pixel area R1 to thicken the thickness of a portion of the cathode layer 5 in the red pixel area R1. Due to the selection performance of the metal patterning layer 6 for the material for the cathode, it is difficult for the redeposited material for the cathode to be deposited on the metal patterning layer 6, that is, the thickened cathode layer is not formed in the green pixel area G1 and the blue pixel area B1, and a portion of the cathode layer 5 with a greater thickness is formed in the red pixel area R1. For example, the portion of the cathode layer formed in the red pixel area R1 for the second time may have a thickness of about 3 nm. Since the thickness of the portion of the cathode layer 5 in the red pixel area R1 is greater than the thicknesses of the portions of the cathode layer 5 in the green pixel area G1 and the blue pixel area B1, the microcavity effect of the top-emission type red light-emitting device can be enhanced, and thus the attenuation in brightness of red light is accelerated. As shown in FIG. 12, the attenuation curve of brightness of red light with the viewing angle and the attenuation curve of brightness of green light with the viewing angle are consistent, the attenuation curves of brightness are improved, and the display effect is improved.

In a specific implementation, in the display substrate provided in the embodiment of the present disclosure, as shown in FIG. 1A, FIG. 2A, FIG. 3A, FIG. 4A, FIG. 5A, FIG. 6A, FIG. 7A, FIG. 8A, FIG. 9A, and FIG. 11, the display substrate is in a top-emission structure, and the display substrate further includes: a thin film transistor 8 located between the base substrate 1 and the anode layer 2, and a planarization layer 9 located between the thin film transistor 8 and the anode layer 2. The thin film transistor 8 includes an active layer 81, a gate electrode 82, a source electrode 83, and a drain electrode 84, and the display substrate further includes: a gate insulating layer 10 between the active layer 81 and the gate electrode 82, an interlayer insulating layer 11 between the gate electrode 82 and the source and drain electrodes 83 and 84. The anode 21 is electrically connected to the drain electrode 84 of the thin film transistor 8, since the anode 21 is electrically connected with the drain electrode 84 of the thin film transistor 8, the display substrate can sequentially turn on each row of thin film transistors through gate scanning signals, each thin film transistor transmits a data voltage to the anode 21, and the anode 21 cooperates with the cathode layer 5 to form a voltage difference for driving the organic light-emitting material in the light-emitting functional layer 4 to emit light, achieving autonomous light-emitting. It should be noted that the thin film transistor 8 in the embodiment of the present disclosure is of a top-gate structure; alternatively, the thin film transistor 8 may be of a bottom-gate structure.

In some implementations, the base substrate in the embodiment of the present disclosure may be a rigid base substrate, such as a glass substrate; alternatively, the base substrate may be a flexible base substrate, for example, the material of the flexible base substrate includes polyimide (PI).

In some implementations, the materials for the anode and the cathode may be selected depending on the structure of the display substrate. For example, the material for the anode is usually selected from transparent or semitransparent materials with high work functions such as indium tin oxide, silver, nickel oxide, graphene, which have good conductivity and chemical stability. For example, the material for the cathode is usually selected from a metal or alloy material having a low work function; the material for the cathode is preferably an alloy of a metal with a low work function and a corrosion-resistant metal, such as, Mg, Ag, Al, Li, K, Ca, MgₓAg₍₁₋ₓ₎, LiₓAl₍₁₋ₓ₎, LiₓCa₍₁₋ₓ₎ or LiₓAg₍₁₋ₓ₎.

The light-emitting functional layer in the embodiment of the present disclosure may include: a hole injection layer, a hole transport layer, an organic light-emitting layer, an electron transport layer, and an electron injection layer, holes injected from the anode layer 2 and electrons injected from the cathode layer 5 combine in the organic light-emitting layer to form excitons, the excitons excite the light-emitting molecules, and the excited light-emitting molecules emit visible light through radiation relaxation.

In some implementations, the material of the pixel defining layer 3 may be, for example, an inorganic material (silicon nitride, silicon oxide, or the like), an organic material (for example, polyimide, polytetrafluoroethylene), or the like, and alternatively, may be a photoresist (such as polyvinyl alcohol, laurate) or the like, which is not limited in any way in the present disclosure.

In some implementations, as shown in FIG. 1A, FIG. 2A, FIG. 3A, FIG. 4A, FIG. 5A, FIG. 6A, FIG. 7A, FIG. 8A, FIG. 9A and FIG. 11, the light-emitting functional layer 4 may include at least one of a light-emitting functional layer (R) that emits red light, a light-emitting functional layer (G) that emits green light or a light-emitting functional layer (B) that emits blue light, but the present disclosure is not limited thereto, and the embodiment of the present disclosure exemplifies that the light-emitting functional layer 4 includes the light-emitting functional layer (R) that emits red light, the light-emitting functional layer (G) that emits green light and the light-emitting functional layer (B) that emits blue light, that is, color display is implemented using three primary colors.

Based on the same inventive concept, an embodiment of the present disclosure further provides a method for manufacturing the above-mentioned display substrate, as shown in FIG. 13, the method may include steps of:
S1301, manufacturing an anode layer including a plurality of anodes arranged at intervals on a base substrate;
S1302, manufacturing a pixel defining layer on a side, away from the base substrate, of the cathode layer, the pixel defining layer defining a plurality of pixel areas and covering edge areas of the anodes;
S1303, manufacturing a light-emitting functional layer on a side of the anode layer, away from the base substrate, the light-emitting functional layer at least covering the pixel areas; and
S1304, manufacturing a cathode layer and a metal patterning layer on a side of the light-emitting functional layer away from the base substrate.

According to the method for manufacturing the display substrate, the cathode layer and the metal patterning layer are formed on the side, away from the base substrate, of the light-emitting functional layer, the position of the metal patterning layer is reasonably arranged, so that the overall transmittance of the display substrate can be improved, in addition, the auxiliary electrode layer electrically connected with the cathode layer is further provided, so that the resistance of the cathode layer can be reduced, and the IR drop of the cathode layer is reduced, therefore, the uniform distribution of voltage drop among the pixel areas can be achieved, thereby improving the uniformity of light emission and display quality of the display substrate.

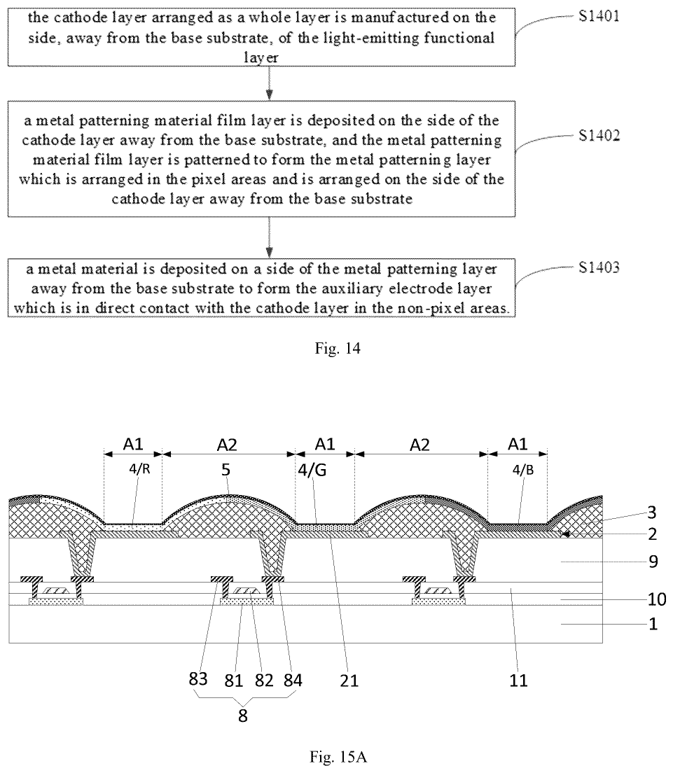

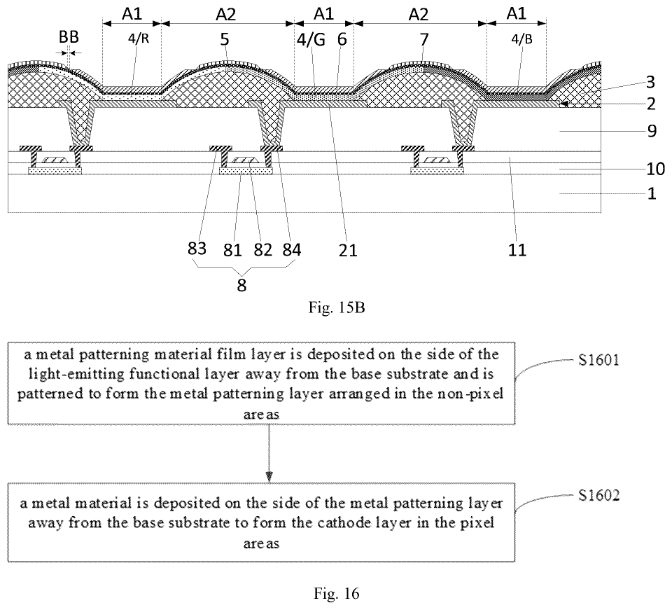

In a specific implementation, in the above method provided in the embodiment of the present disclosure, as shown in FIG. 14, the manufacturing the cathode layer and the metal patterning layer on the side of the light-emitting functional layer away from the base substrate may specifically include steps S1401 to S1403.

At step S1401, the cathode layer arranged as a whole layer is manufactured on the side, away from the base substrate, of the light-emitting functional layer.

Specifically, taking the structure shown in FIG. 1A as an example, first, the thin film transistor 8, the planarization layer 9, the anode layer 2, the pixel defining layer 3, the light-emitting functional layer 4, and the cathode layer 5 are sequentially formed on the base substrate base 1, as shown in FIG. 15A.

At step S1402, a metal patterning material film layer is deposited on the side of the cathode layer away from the base substrate, and the metal patterning material film layer is patterned to form the metal patterning layer which is arranged in the pixel areas and is arranged on the side of the cathode layer away from the base substrate.

Specifically, the metal patterning material film layer is deposited on the side of the cathode layer 5 away from the base substrate 1 by evaporation, printing, sputtering, or the like, and is patterned, so that the metal patterning layer 6 disposed in the pixel areas A1 and on the side of the cathode layer 5 away from the base substrate 1 is formed, as shown in FIG. 15B.

At step S1403, a metal material is deposited on a side of the metal patterning layer away from the base substrate to form the auxiliary electrode layer which is in direct contact with the cathode layer in the non-pixel areas.

Specifically, the metal material is deposited on the side of the metal patterning layer 6 away from the base substrate 1, so that the auxiliary electrode layer 7 in direct contact with the cathode layer 5 is formed only in the non-pixel areas A2 due to the selectivity of the metal patterning layer 6 to the metal material, as shown in FIG. 1A, and the resistance of the cathode layer 5 is reduced.

In a specific implementation, in the above method provided in the embodiment of the present disclosure, as shown in FIG. 16, the manufacturing the cathode layer and the metal patterning layer on the side of the light-emitting functional layer away from the base substrate may specifically include steps S1601 and S1602.

At step S1601, a metal patterning material film layer is deposited on the side of the light-emitting functional layer away from the base substrate and is patterned to form the metal patterning layer arranged in the non-pixel areas.

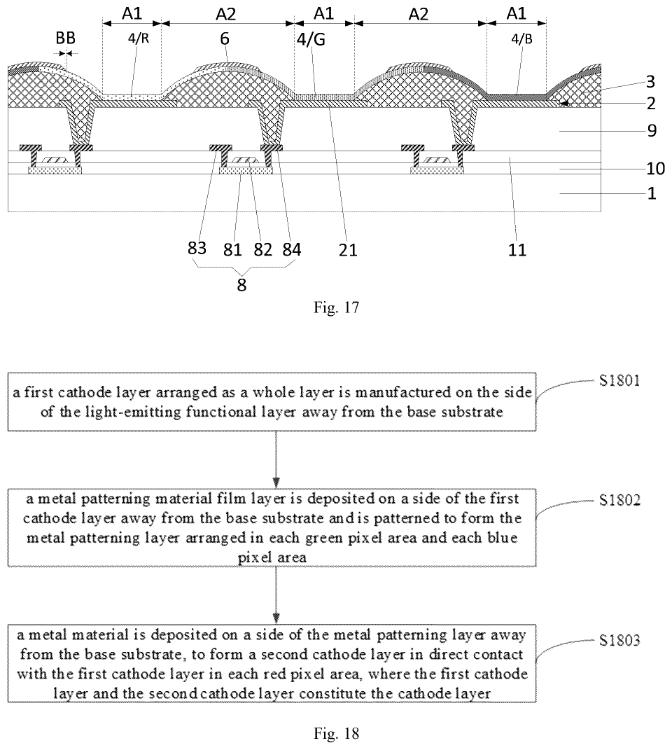

Specifically, taking the structure shown in FIG. 8A as an example, first, the thin film transistor 8, the planarization layer 9, the anode layer 2, the pixel defining layer 3, and the light-emitting functional layer 4 are sequentially formed on the base substrate 1, and the metal patterning material film layer is deposited on the side of the light-emitting functional layer 4 away from the base substrate 1 by a process such as vapor deposition, printing, sputtering, or the like, and is patterned to form the metal patterning layer 6 arranged in the non-pixel areas A2, as shown in FIG. 17.

At step S1602, a metal material is deposited on the side of the metal patterning layer away from the base substrate to form the cathode layer in the pixel areas.

Specifically, the metal material is deposited on the side of the metal patterning layer 6 away from the base substrate 1, and due to the selectivity of the metal patterning layer 6 to the metal material, the cathode layer 5 (51) is formed only in the pixel areas A1, as shown in FIG. 8A, so that the overall display effect of the display substrate is improved.

In a specific implementation, in the above method provided in the embodiment of the present disclosure, as shown in FIG. 18, the manufacturing the cathode layer and the metal patterning layer on the side of the light-emitting functional layer away from the base substrate may specifically include steps S1801 to S1803.

At step S1801, a first cathode layer arranged as a whole layer is manufactured on the side of the light-emitting functional layer away from the base substrate.

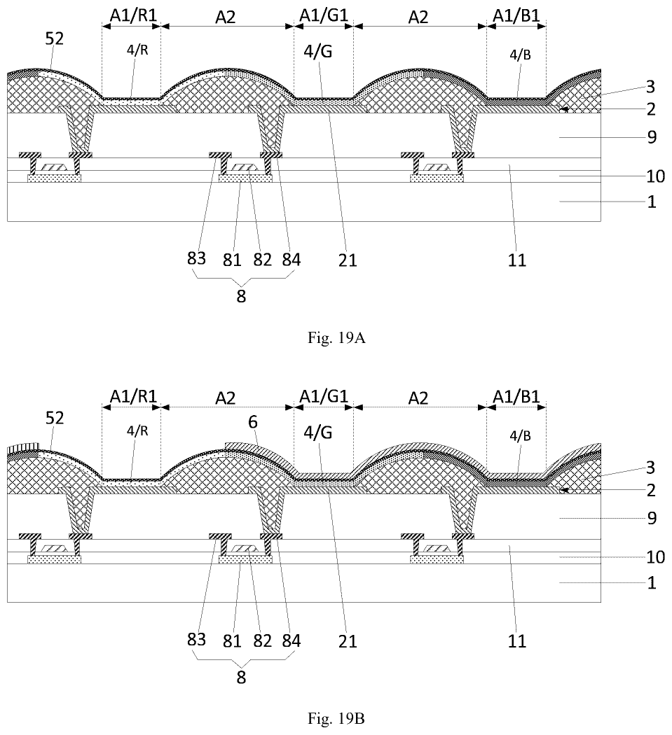

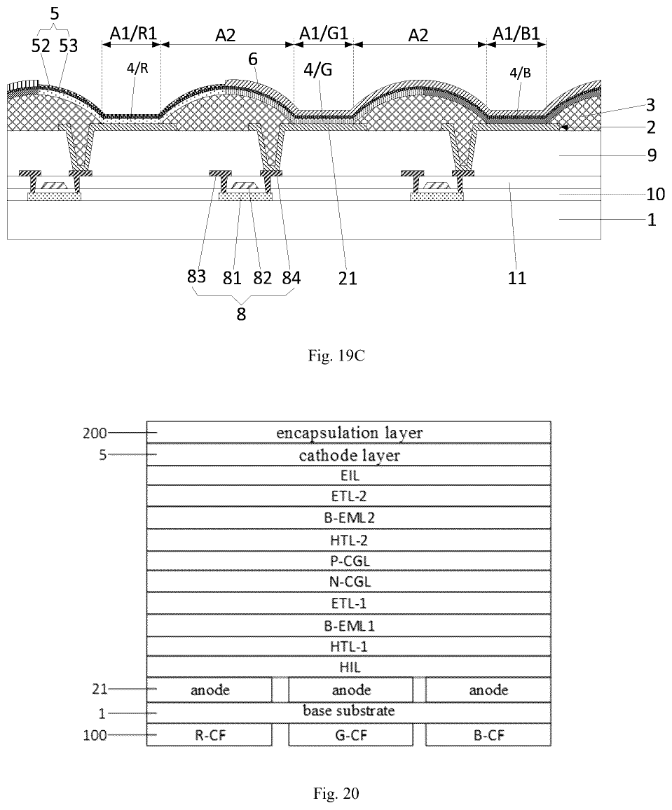

Specifically, taking the structure shown in FIG. 10 as an example, first, the thin film transistor 8, the planarization layer 9, the anode layer 2, the pixel defining layer 3, the light-emitting functional layer 4, and the first cathode layer 52 are sequentially formed on the base substrate base substrate 1, as shown in FIG. 19A.

At step S1802, a metal patterning material film layer is deposited on a side of the first cathode layer away from the base substrate and is patterned to form the metal patterning layer arranged in each green pixel area and each blue pixel area.

Specifically, the metal patterning material film layer is deposited on the side of the first cathode layer 52 away from the base substrate 1 by evaporation, printing, sputtering, or the like, and is patterned to form the metal patterning layer 6 disposed in the green pixel area G1 and the blue pixel area B1, as shown in FIG. 19B.

At step S1803, a metal material is deposited on a side of the metal patterning layer away from the base substrate, to form a second cathode layer in direct contact with the first cathode layer in each red pixel area, where the first cathode layer and the second cathode layer constitute the cathode layer.

Specifically, the metal material is deposited on the side of the metal patterning layer 6 away from the base substrate 1, and due to the selectivity of the metal patterning layer 6 to the metal material, the second cathode layer 53 in direct contact with the first cathode layer 52 is formed only in the red pixel area R1, and the first cathode layer 52 and the second cathode layer 53 constitute the cathode layer 5, so that the thickness of a portion of the cathode layer 5 corresponding to the red pixel area R1 is greater than the thicknesses of portions of the cathode layer 5 corresponding to the green pixel area G1 and the blue pixel area B1, as shown in FIG. 19C, and the display effect can be improved.

Based on the same inventive concept, an embodiment of the present disclosure further provides a display apparatus, which includes the display substrate provided by the embodiment of the present disclosure. Since the principle of solving the problems of the display apparatus is similar to that of the display substrate, the implementation of the display apparatus can be referred to the implementation of the display substrate mentioned above, and repetition is omitted.

In a specific implementation, the display apparatus provided in the embodiment of the present invention may be an organic light-emitting display apparatus, and is not limited herein.

In a specific implementation, as shown in FIG. 20, the display apparatus provided in the embodiment of the present disclosure further includes: a color filter layer 100 arranged on a side of the base substrate 1 away from the cathode layer 5, and an encapsulation layer 200 arranged on a side of the cathode layer 5 away from the base substrate 1. The color filter layer 100 includes a red filter (R-CF), a green filter (G-CF), and a blue filter (B-CF).

The light-emitting functional layer 4 includes a hole injection layer (HIL), a first hole transport layer (HTL-1), a first blue light-emitting layer (B-EML1), a first electron transport layer (ETL-1), an N-type charge generation layer (N-CGL), a P-type charge generation layer (P-CGL), a second hole transport layer (HTL-2), a second blue light-emitting layer (B-EML2), a second electron transport layer (ETL-2) and an electron injection layer (EIL) which are sequentially stacked and arranged between the anode 21 and the cathode layer 5, and the hole injection layer (HIL) is close to the anode 21.

The structure in FIG. 20 adopts a tandem bottom-emission white OLED device as a light source, and achieves R/G/B full color display through a color filter (CF) disposed on another side of the base substrate 1.

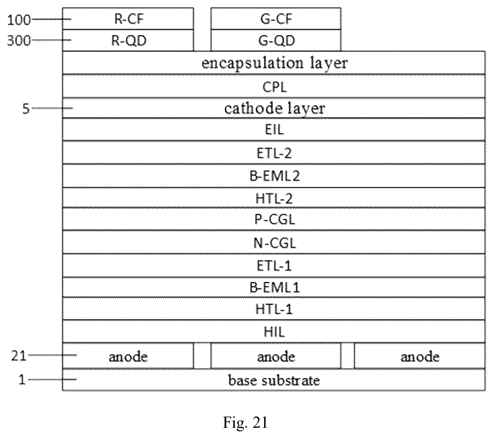

In a specific implementation, as shown in FIG. 21, the display apparatus provided in the embodiment of the present disclosure further includes: a light extraction layer (CPL), the encapsulation layer 200, a quantum dot color conversion layer 300 and the color filter layer 100, which are sequentially stacked and arranged on the side of the cathode layer 5 away from the base substrate 1. The quantum dot color conversion layer 300 includes a red quantum dot color conversion layer (R-QD) and a green quantum dot color conversion layer (G-QD), and the color filter layer 100 includes a red filter (R-CF) and a green filter (G-CF).

The light-emitting functional layer 4 includes a hole injection layer (HIL), a first hole transport layer (HTL-1), a first blue light-emitting layer (B-EML1), a first electron transport layer (ETL-1), an N-type charge generation layer (N-CGL), a P-type charge generation layer (P-CGL), a second hole transport layer (HTL-2), a second blue light-emitting layer (B-EML2), a second electron transport layer (ETL-2) and an electron injection layer (EIL) which are sequentially stacked and arranged between the anode 21 and the cathode layer 5, and the hole injection layer (HIL) is close to the anode 21.

In the structure of FIG. 21, the QD color conversion layers located above the cathode layer 5 are excited by a tandem top-emission blue OLED device to realize full color display.

In a specific implementation, the display apparatus provided in the embodiment of the present invention may be a full-screen display apparatus, or may be a flexible display apparatus, or the like, which is not limited herein.

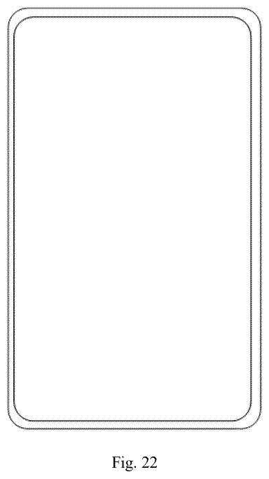

In a specific implementation, the display apparatus provided in the embodiment of the present disclosure may be a full-screen mobile phone as shown in FIG. 22. Alternatively, the display apparatus provided in the embodiment of the present invention may be any product or component having a display function, such as a tablet computer, a television, a display, a notebook computer, a digital photo frame, a navigator, or the like. Other essential components of the display apparatus are understood by those skilled in the art, and are not described herein or should not be construed as limiting the present disclosure.

The embodiments of the present disclosure provide a display substrate, a method for manufacturing the display substrate and a display apparatus, where, the cathode layer and the metal patterning layer are arranged on the side of the light-emitting functional layer away from the base substrate, the position of the metal patterning layer is reasonably arranged, so that the overall transmittance of the display substrate can be improved, in addition, the auxiliary electrode layer connected with the cathode layer is further provided, so that the resistance of the cathode layer can be reduced, the IR drop of the cathode layer is reduced, uniform distribution of the voltage drop among the pixel areas is realized, and the uniformity of light emission and the display quality of the display substrate are improved.

While the embodiments of the present disclosure have been described, additional variations and modifications in those embodiments may occur to those skilled in the art once they learn of the basic concept. Therefore, it is intended that the appended claims should be interpreted as including the embodiments and all variations and modifications that fall within the scope of the present disclosure.

It will be apparent to those skilled in the art that various changes and modifications may be made in the embodiments of the disclosure without departing from the spirit and scope of the embodiments of the present disclosure. Thus, if such modifications and variations of the embodiments of the present disclosure are within the scope of the claims of the present disclosure and their equivalents, the present disclosure is also intended to encompass such modifications and changes.

1. A display substrate, comprising:
a base substrate;
an anode layer arranged on the base substrate and comprising a plurality of anodes arranged at intervals;
a pixel defining layer disposed on the base substrate, the pixel defining layer defining a plurality of pixel areas and covering an edge area of each of the anodes;
a light-emitting functional layer arranged on a side of the anode layer away from the base substrate, the light-emitting functional layer at least covering the pixel areas; and
a cathode layer and a metal patterning layer arranged on a side of the light-emitting functional layer away from the base substrate.

2. The display substrate of claim 1, wherein the cathode layer is disposed as a whole layer, the metal patterning layer is disposed on a side of the cathode layer away from the base substrate, and the metal patterning layer is disposed in the pixel areas;
the display substrate further comprises non-pixel areas between the pixel areas, and the display substrate further comprises an auxiliary electrode layer arranged in the non-pixel areas, the auxiliary electrode layer being arranged on the side of the cathode layer away from the base substrate, and the auxiliary electrode layer being in direct contact with the cathode layer.

3. The display substrate of claim 2, wherein the auxiliary electrode layer is overlapped with the metal patterning layer to form an overlapping region therebetween, or the auxiliary electrode layer is not overlapped with the metal patterning layer.

4. The display substrate of claim 3, wherein the auxiliary electrode layer is overlapped with the metal patterning layer to form an overlapping region therebetween, and wherein
the metal patterning layer has a thickness ranging from 60 nm to 100 nm, the auxiliary electrode layer has a thickness ranging from 40 nm to 60 nm, an edge area of the metal patterning layer has a slope angle ranging from 1° to 20°, an edge area of the auxiliary electrode layer has a slope angle ranging from 5° to 20°, and the overlapping region has a width ranging from 1 μm to 5 μm; or
the metal patterning layer has a thickness ranging from 60 nm to 100 nm, the auxiliary electrode layer has a thickness ranging from 20 nm to 40 nm, an edge area of the metal patterning layer has a slope angle ranging from 1° to 20°, an edge area of the auxiliary electrode layer has a slope angle ranging from 10° to 50°, and the overlapping region has a width less than 1 μm; or
the metal patterning layer has a thickness ranging from 10 nm to 30 nm, the auxiliary electrode layer has a thickness more than 100 nm, an edge area of the metal patterning layer has a slope angle ranging from 1° to 20°, an edge area of the auxiliary electrode layer has a slope angle ranging from 160° to 179°, and the overlapping region has a width ranging from 3 μm to 6 μm; or
the metal patterning layer has a thickness ranging from 10 nm to 30 nm, the auxiliary electrode layer has a thickness ranging from 30 nm to 100 nm, an edge area of the metal patterning layer has a slope angle ranging from 0.5° to 15°, an edge area of the auxiliary electrode layer has a slope angle ranging from 165° to 179.5°, and the overlapping region has a width ranging from 1 μm to 3 μm; or
the metal patterning layer has a thickness ranging from 10 nm to 30 nm, the auxiliary electrode layer has a thickness ranging from 10 nm to 30 nm, an edge area of the metal patterning layer has a slope angle ranging from 0.1° to 30°, an edge area of the auxiliary electrode layer has a slope angle ranging from 150° to 179.9°, and the overlapping region has a width ranging from 0 μm to 1 μm.

5-9. (canceled)

10. The display substrate of claim 4, wherein the auxiliary electrode layer is not overlapped with the metal patterning layer, the metal patterning layer has a thickness ranging from 60 nm to 100 nm, the auxiliary electrode layer has a thickness ranging from 10 nm to 20 nm, an edge area of the metal patterning layer has a slope angle ranging from 1° to 20°, an edge area of the auxiliary electrode layer has a slope angle ranging from 30° to 90°, and a gap between adjacent edges of the auxiliary electrode layer and the metal patterning layer has a width ranging from 1 μm to 5 μm.

11. The display substrate of claim 3, further comprising a light extraction layer disposed between the cathode layer and the metal patterning layer, the light extraction layer having a pattern identical to a pattern of the metal patterning layer.

12. The display substrate of claim 11, wherein the light extraction layer has a thickness ranging from 60 nm to 100 nm, the metal patterning layer has a thickness ranging from 10 nm to 30 nm, the auxiliary electrode layer has a thickness ranging from 30 nm to 100 nm, an edge area of the auxiliary electrode layer has a slope angle ranging from 90° to 170°, the auxiliary electrode layer is overlapped with the metal patterning layer to form an overlapping region therebetween, and the overlapping region has a width ranging from 0 μm to 1 μm.

13. The display substrate of claim 2, wherein a ratio of an area of the auxiliary electrode layer to an area of a display area of the display substrate ranges from 30% to 80%.

14. The display substrate of claim 1, wherein the metal patterning layer is provided on the side of the light-emitting functional layer away from the base substrate, and the metal patterning layer is provided in non-pixel areas between adjacent pixel areas; and
the cathode layer includes cathodes disposed in the pixel areas.

15. The display substrate of claim 14, wherein each cathode is overlapped with the metal patterning layer to form an overlapping region therebetween, and
the metal patterning layer has a thickness ranging from 60 nm to 100 nm, each cathode has a thickness ranging from 10 nm to 20 nm, an edge area of the metal patterning layer has a slope angle ranging from 1° to 20°, an edge area of each cathode has a slope angle ranging from 1° to 30°, and the overlapping region has a width ranging from 1 μm to 5 μm.

16. (canceled)

17. The display substrate of claim 14, wherein each cathode is not overlapped with the metal patterning layer, and
the metal patterning layer has a thickness ranging from 60 nm to 100 nm, each cathode has a thickness ranging from 1 nm to 10 nm, an edge area of the metal patterning layer has a slope angle ranging from 1° to 20°, an edge area of each cathode has a slope angle ranging from 3° to 90°, and a gap between adjacent edges of each cathode and the metal patterning layer has a width ranging from 0.1 μm to 2 μm.

18. (canceled)

19. The display substrate of claim 1, wherein the pixel areas include a red pixel area, a green pixel area, and a blue pixel area, the cathode layer is disposed as a whole layer, the metal patterning layer is disposed on a side of the cathode layer away from the base substrate, and the metal patterning layer is disposed in the green pixel area and the blue pixel area, a thickness of a portion of the cathode layer corresponding to the red pixel area is greater than each of thicknesses of portions of the cathode layer corresponding to the green pixel area and the blue pixel area, the thicknesses of the portions of the cathode layers corresponding to the green pixel area and the blue pixel area being the same.

20. The display substrate of claim 1, wherein a material of the metal patterning layer is an organic transparent material and the metal patterning layer has a transmittance greater than 90%.

21. The display substrate of claim 20, wherein the material of the metal patterning layer comprises:
N,N′-diphenyl-N,N-bis(9-phenyl-9H-carbazol-3-yl)biphenyl-4,4′-diamine, N-(biphenyl-4-yl)-9,9-dimethyl-N-(4-(9-phenyl-9H-carbazol-3-yl)phenyl)-9H-fluoren-2-amine, 4,4′,4″-tris(3-methylphenylphenylamino)triphenylamine, N,N′-bis(1-naphthyl)-N,N′-diphenyl[1,1′-biphenyl]-4,4′-diamine, 4,4′-bis[N-(3-methylphenyl)-N-phenylamino]biphenyl, N4,N4′-diphenyl-N4,N4′-bis(9-phenyl-9H-carbazol-3-yl)diphenyl-4,4′-diamine, or N(diphenyl-4-yl)9,9-dimethyl-N-(4(9-phenyl-9H-carbazol-3-yl)phenyl)-9H-fluoren-2-amine.

22. The display substrate of claim 2, wherein the auxiliary electrode layer comprises a single layer of metal; or
the auxiliary electrode layer comprises at least two layers of metal which are stacked together and different in material, and wherein
the material of each layer of the metal comprises Mg, Ag, Al, Li, K, Ca, MgₓAg₍₁₋ₓ₎, LiₓAl₍₁₋ₓ₎, LiₓCa₍₁₋ₓ₎, or LiₓAg₍₁₋ₓ₎.

23. (canceled)

24. A display apparatus, comprising the display substrate of claim 1.

25. The display apparatus of claim 24, further comprising: a color filter layer arranged on a side of the base substrate away from the cathode layer, and an encapsulation layer arranged on a side of the cathode layer away from the base substrate, wherein
the light-emitting functional layer comprises a hole injection layer, a first hole transport layer, a first blue light-emitting layer, a first electron transport layer, an N-type charge generation layer, a P-type charge generation layer, a second hole transport layer, a second blue light-emitting layer, a second electron transport layer and an electron injection layer which are sequentially stacked and arranged between the anodes and the cathode layer, and the hole injection layer is close to the anodes.

26. The display apparatus of claim 24, further comprising: a light extraction layer, an encapsulation layer, a quantum dot color conversion layer and a color filter layer which are stacked together and arranged on a side of the cathode layer away from the base substrate, wherein
the light-emitting functional layer comprises a hole injection layer, a first hole transport layer, a first blue light-emitting layer, a first electron transport layer, an N-type charge generation layer, a P-type charge generation layer, a second hole transport layer, a second blue light-emitting layer, a second electron transport layer and an electron injection layer which are sequentially stacked and arranged between the anodes and the cathode layer, and the hole injection layer is close to the anodes.

27. A method for manufacturing the display substrate of claim 1, comprising:
manufacturing the anode layer comprising the plurality of anodes arranged at intervals on the base substrate;
manufacturing the pixel defining layer on the side of the cathode layer away from the base substrate, the pixel defining layer defining the plurality of pixel areas and covering the edge area of each anode;
manufacturing the light-emitting functional layer on the side of the anode layer away from the base substrate, the light-emitting functional layer at least covering the pixel areas; and
manufacturing the cathode layer and the metal patterning layer on the side of the light-emitting functional layer away from the base substrate.

28. The method of claim 27, wherein the manufacturing the cathode layer and the metal patterning layer on the side of the light-emitting functional layer away from the base substrate comprises:
manufacturing the cathode layer arranged as a whole layer on the side of the light-emitting functional layer away from the base substrate;
depositing a metal patterning material film layer on a side of the cathode layer away from the base substrate, and patterning the metal patterning material film layer to form the metal patterning layer which is arranged in the pixel areas and is arranged on the side of the cathode layer away from the base substrate; and
depositing a metal material on a side of the metal patterning layer away from the base substrate to form an auxiliary electrode layer, which is in direct contact with the cathode layer, in non-pixel areas, or
the manufacturing the cathode layer and the metal patterning layer on the side of the light-emitting functional layer away from the base substrate comprises:
depositing a metal patterning material film layer on the side of the light-emitting functional layer away from the base substrate, and patterning the metal patterning material film layer to form the metal patterning layer arranged in non-pixel areas; and
depositing a metal material on a side of the metal patterning layer away from the base substrate to form the cathode layer in the pixel areas, or
the manufacturing the cathode layer and the metal patterning layer on the side of the light-emitting functional layer away from the base substrate comprises:
manufacturing a first cathode layer arranged as a whole layer on the side of the light-emitting functional layer away from the base substrate;
depositing a metal patterning material film layer on a side of the first cathode layer away from the base substrate, and patterning the metal patterning material film layer to form the metal patterning layer in a green pixel area and a blue pixel area; and
depositing a metal material on a side of the metal patterning layer away from the base substrate, to form a second cathode layer which is in direct contact with the first cathode layer in a red pixel area, the first cathode layer and the second cathode layer constituting the cathode layer.

29-30. (canceled)
